(19) United States
(12) Patent Application Publication
(10) Pub. No.: US 2026/0103620 A1
(43) Pub. Date: Apr. 16, 2026

(54) SLURRY COMPOSITION FOR CHEMICAL MECHANICAL POLISHING AND METHOD OF MANUFACTURING SEMICONDUCTOR DEVICE USING THE SAME

(71) Applicant: Samsung Electronics Co., Ltd., Suwon-si (KR)

(72) Inventors: Wansu SONG, Suwon-si (KR); Donghoon KWON, Suwon-si (KR)

(21) Appl. No.: 19/095,277

(22) Filed: Mar. 31, 2025

(30) Foreign Application Priority Data
Oct. 10, 2024 (KR) 10-2024-0137228

(51) Int. Cl. C09G 1/02; H01L 21/3205; H01L 21/321

(52) U.S. Cl. CPC C09G 1/02; H10P 14/412; H10P 52/403

(57) ABSTRACT

According to some aspects of the present disclosure, a slurry composition for chemical mechanical polishing may include polishing particles including a piezoelectric material, and an oxidizing agent, wherein the piezoelectric material may include a first piezoelectric material and a second piezoelectric material bonded to the first piezoelectric material, and the first piezoelectric material and the second piezoelectric material may have different bandgaps from each other.

### CROSS-REFERENCE TO RELATED APPLICATION

This U.S. non-provisional application claims priority to Korean Patent Application No. 10-2024-0137228, filed in the Korean Intellectual Property Office on Oct. 10, 2024, the entire contents of which are hereby incorporated by reference.

### BACKGROUND

### Technical Field

The present disclosure relates to a slurry composition for chemical mechanical polishing and a method of manufacturing a semiconductor device using the same.

### Description of Related Art

In general, a chemical mechanical polishing (CMP) process is used in semiconductor device manufacturing for global planarization of the wafer surface. The metal film for use as an interconnect layer of the semiconductor device is made of a material that is thermochemically stable, has a low electrical resistance, and exhibits good adhesion when formed as a thin film, but this makes removal of the metal film during the CMP process difficult. Therefore, a method is used, in which ferric-based additives are reacted with oxidizing agents to generate OH radicals and the OH radicals are reacted with the metal film to form metal oxides that are relatively easily polished, after which the CMP process is performed. However, there is a problem in that ferric series additives cause damage to the CMP device, which reduces the lifetime of the CMP device.

### SUMMARY

To address one or more problems (e.g., the problems described above and/or other problems not explicitly described herein), the present disclosure provides a slurry composition for chemical mechanical polishing and a method of manufacturing a semiconductor device using the same.

According to some aspects of the present disclosure, a slurry composition for chemical mechanical polishing may include polishing particles including a piezoelectric material, and an oxidizing agent, in which the polishing particles include a first particle including a first piezoelectric material, and a second particle including a second piezoelectric material, the piezoelectric material may include the first piezoelectric material and the second piezoelectric material bonded to the first piezoelectric material, and the first piezoelectric material and the second piezoelectric material may have different bandgaps from each other.

According to some aspects of the present disclosure, a slurry composition for chemical mechanical polishing may include polishing particles including a piezoelectric material, and an oxidizing agent, in which the polishing particles include a first particle including a first piezoelectric material, and a second particle including a second piezoelectric material, the piezoelectric material may include the first piezoelectric material and the second piezoelectric material bonded to the first piezoelectric material, and the first piezoelectric material and the second piezoelectric material may differ from each other in at least one of a particle size or a material thereof.

According to some aspects of the present disclosure, a method of manufacturing a semiconductor device may include forming a metal film on a substrate, and performing a chemical mechanical polishing process on the metal film using a slurry composition for chemical mechanical polishing, in which the slurry composition for chemical mechanical polishing may include polishing particles including a piezoelectric material, and an oxidizing agent, wherein the polishing particles include a first particle including a first piezoelectric material, and a second particle including a second piezoelectric material, and the piezoelectric material may include the first piezoelectric material and the second piezoelectric material bonded to the first piezoelectric material, and a first bandgap of the first piezoelectric material and a second bandgap of the second piezoelectric material may be different from each other.

According to some aspects of the present disclosure, by generating OH radicals from oxidizing agents using polishing particles including piezoelectric materials, damage to the CMP device can be minimized and accordingly, the life and stability of the CMP device can be improved. In addition, by bonding the piezoelectric materials having different bandgaps, the recombination of the electron-hole pairs generated during the CMP process can be suppressed, thereby improving the piezoelectric efficiency. Accordingly, the oxidation reaction of the metal film can be promoted, enabling an efficient CMP process.

### BRIEF DESCRIPTION OF THE DRAWINGS

The above and other embodiments and features of the present disclosure will become more apparent by describing in detail example embodiments thereof with reference to the attached drawings, in which:

FIG. 1 is a diagram illustrating a chemical mechanical polishing apparatus according to some aspects;

FIG. 2 is a diagram illustrating a slurry composition for chemical mechanical polishing according to some aspects;

FIG. 3 is a diagram illustrating polishing particles and a polishing mechanism of a metal film using the same according to some aspects;

FIG. 4 is a diagram illustrating polishing particles according to some aspects;

FIG. 5 is a diagram illustrating polishing particles according to some aspects;

FIG. 6 is a diagram illustrating polishing particles according to some aspects;

FIGS. 7 and 8 are diagrams illustrating polishing particles according to some aspects;

FIGS. 9 and 10 are diagrams illustrating polishing particles according to some aspects;

FIG. 11 is a flowchart provided to explain a method of manufacturing a semiconductor device according to some aspects; and

FIGS. 12 to 16 are diagrams sequentially illustrating a method of manufacturing a semiconductor device according to some aspects.

### DETAILED DESCRIPTION

A slurry composition for chemical mechanical polishing and a method of manufacturing a semiconductor device using the slurry composition according to some aspects of the present disclosure will be described in detail with reference to the drawings. In addition, the term “piezoelectric material” as used herein may refer to a material that generates a voltage in response to mechanical deformation.

It will be understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

It will be understood that, although the terms first, second, etc. may be used herein to describe various elements, components, or materials, these elements, components, or materials should not be limited by these terms. Unless the context indicates otherwise, these terms are only used to distinguish one element, component, or material from another element, component, or material, for example as a naming convention.

Items described in the singular herein may be provided in plural, as can be seen, for example, in the drawings. Thus, the description of a single item that is provided in plural should be understood to be applicable to the remaining plurality of items unless context indicates otherwise.

The semiconductor device may be a semiconductor chip (i.e., a semiconductor device singulated from (e.g., cut from) a wafer).

As used herein, “particle size” refers to the diameter size of individual particles. It should be understood that within a group or set of particles, some particles may fall outside the “particle size” indicated herein. For example, a mean or median particle diameter size may be within the indicated size and fall within the scope of embodiments of the present application, even if there are some outlying particles that have a particle diameter size smaller or larger than the indicated size.

As used herein the term “on” or “disposed on” is intended to mean that an element is over or on or aside another element. The elements may be touching or not. An element need not cover an entire surface of an element to be considered “on” or “disposed on” the element. The term is intended to encompass one element disposed on all or any part of another element.

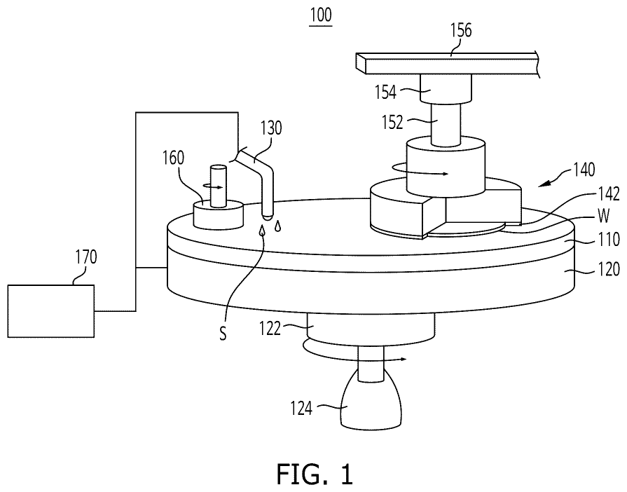

FIG. 1 is a diagram illustrating a chemical mechanical polishing apparatus according to some aspects. The chemical mechanical polishing apparatus 100 according to FIG. 1 is only an example, and the technical idea of the present invention is not limited thereto. Referring to FIG. 1, the chemical mechanical polishing apparatus according to some aspects may include a polishing pad 110, a platen 120, a slurry supply unit 130, a carrier head assembly 140, a pad conditioner 160, a control system 170, etc.

The polishing pad 110 may be disposed on the platen 120. The polishing pad 110 may be provided as a plate such as a circular plate having a predetermined thickness, but is not limited thereto. The polishing pad 110 may include a polishing surface having a predetermined roughness. While the chemical mechanical polishing process is performed, the polishing surface of the polishing pad 110 may be in contact with a wafer W to polish the wafer W.

The polishing pad 110 may include a porous material having a plurality of microspaces. The microspaces of the polishing pad 110 may accommodate the polishing slurry S provided during the chemical mechanical polishing process. For example, the polishing pad 110 may include a polyurethane pad, but is not limited thereto.

In some aspects, the polishing pad 110 may further include a conductive material. The polishing pad 110, which is a conductive material, may be grounded to prevent the occurrence of a short. In other aspects, the polishing pad 110 may be an insulator. For example, the polishing surface of the polishing pad 110 may include a diamond material.

The platen 120 may be rotatable. The rotatable platen 120 may rotate the polishing pad 110 disposed on the platen 120. For example, a first drive shaft 122 connected to a lower portion of the platen 120 may be rotated by a rotational force received from a first motor 124. The platen 120 may rotate the polishing pad 110 around a rotation axis perpendicular to an upper surface of the platen 120.

The slurry supply unit 130 may be disposed adjacent to the polishing pad 110. While the chemical mechanical polishing process is performed, the slurry supply unit 130 may supply the polishing slurry S onto the polishing pad 110. The polishing slurry S may include a slurry composition for chemical mechanical polishing described herein. For example, the polishing slurry S may include polishing particles, an oxidizing agent, a pH adjusting agent, a solvent, etc.

The carrier head assembly 140 may be disposed adjacent to the polishing pad 110. The carrier head assembly 140 may provide the wafer W on the polishing pad 110. The carrier head assembly 140 may be operated to hold the wafer W with respect to the polishing pad 110. The carrier head assembly 140 may independently control polishing parameters (e.g., pressure, etc.) related to each wafer W.

For example, the carrier head assembly 140 may include a retaining ring 142 for holding the wafer W under a flexible membrane. The carrier head assembly 140 may include a plurality of pressurizable chambers that are defined by the flexible membrane and are independently controllable. The pressurizable chambers may apply independently controllable pressure to related regions on the flexible membrane or to related regions on the wafer W.

The carrier head assembly 140 may be rotatable. The rotatable carrier head assembly 140 may rotate the wafer W fixed to the carrier head assembly 140. For example, a second drive shaft 152 connected to an upper portion of the carrier head assembly 140 may be rotated by a rotational force received from a second motor 154.

The carrier head assembly 140 may be supported by a support structure 156 (e.g. support). For example, the support structure 156 may be a carousel or a track, but is not limited thereto. In some aspects, the carrier head assembly 140 may translate laterally across an upper surface of the polishing pad 110. For example, the carrier head assembly 140 may vibrate on the slider of the support structure 156 or may be vibrated by the rotational vibration of the support structure 156 itself.

FIG. 1 illustrates only one carrier head assembly 140 provided on the polishing pad 110, but this is only an example. As another example, in order to efficiently utilize the surface area of the polishing pad 110, a plurality of carrier head assemblies 140 may be provided on the polishing pad 110. In addition, FIG. 1 illustrates that the platen 120 and the carrier head assembly 140 are rotated in the same direction only, but this is only an example, and the platen 120 and the carrier head assembly 140 may be rotated in different rotation directions.

The pad conditioner 160 may be disposed adjacent to the polishing pad 110. The pad conditioner 160 may perform a conditioning process on the polishing pad 110. The pad conditioner 160 may maintain the polishing surface of the polishing pad 110 stable so that the wafer W is effectively polished during the chemical mechanical polishing process.

The control system 170 may control the rotation of the platen 120. The control system 170 may include a controller such as a general-purpose programmable digital computer, an output device for outputting such as a monitor, and an input device for inputting such as a keyboard. The control system may be connected to the slurry supply unit 130 to control the supply of the slurry.

In some aspects, the control system 170 may control the polishing temperature at which the chemical mechanical polishing process is performed on the wafer W. For example, the control system 170 may heat or cool to control the temperature of the polishing pad 110 connected to the platen 120 and disposed on the platen 120. Alternatively, for example, the control system 170 may be connected to the slurry supply unit 130 to heat or cool to control the temperature of the polishing slurry S supplied from the slurry supply unit 130. For example, the control system 170 may include a temperature controlling device, etc., but is not limited thereto.

The chemical mechanical polishing apparatus according to some aspects may minimize damage by using a slurry composition for chemical mechanical polishing, which will be described herein. Specifically, the polishing particles of the polishing slurry S supplied from the slurry supply unit 130 may include a piezoelectric material such that oxidation of the metal film may be induced without a ferric-based additive. As a result, the life and stability of the chemical mechanical polishing apparatus according to some aspects may be improved.

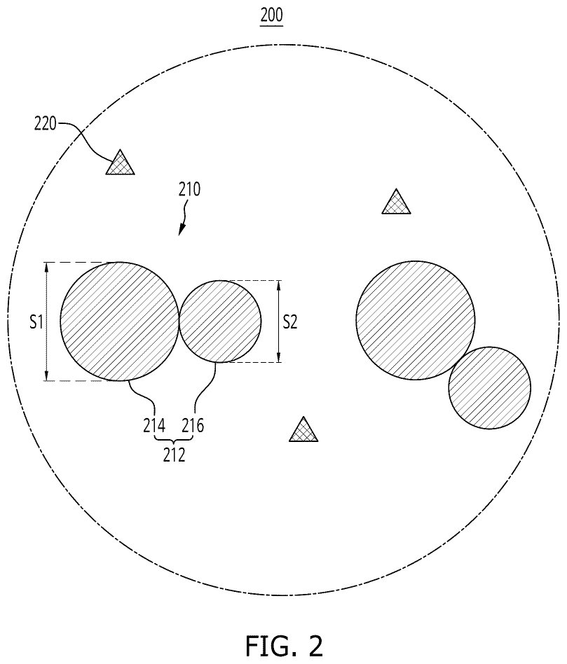

FIG. 2 is a diagram illustrating a slurry composition for chemical mechanical polishing according to some aspects. Referring to FIG. 2, the slurry composition 200 for chemical mechanical polishing according to some aspects may include polishing particles 210 including a piezoelectric material 212 and an oxidizing agent 220.

The polishing particles 210 may serve as an abrasive. Although spherical particles are depicted in FIG. 2, the shape of the polishing particles 210 may be spherical, angular, acicular, plate-like, or a combination of these, but is not particularly limited. The polishing particles 210 may include the piezoelectric material 212. Specifically, the piezoelectric material 212 may include or be at least one of polyvinylidene fluoride (PVDF), polyvinylidene fluoride-co-trifluoroethylene (PVDF-TrFE), poly L-lactic acid (PLLA), barium titanate (BaTiO₃), aluminum nitride (AlN), lithium titanate (LiTiO₃), lead zirconate titanate (Pb(ZrTi)O₃), piezoelectric ceramic, zinc oxide (ZnO), quartz (SiO₂), or titanium dioxide (TiO₂).

The content of the polishing particles 210 may be for example, about 0.1 wt % to about 20 wt % based on 100 wt % of the slurry composition 200 for chemical mechanical polishing. If the content of the polishing particles 210 is less than 0.1 wt %, the polishing speed for the film to be polished may be reduced. If the content of the polishing particles 210 exceeds about 20 wt %, surface defects may occur on the film to be polished, and it may be difficult to adjust the polishing selectivity. According to further example embodiments, the content of the polishing particles 210 may be 0.5 wt % to 18 wt % or 1 wt % to 16 wt % based on 100 wt % of the slurry composition 200 for chemical mechanical polishing.

The oxidizing agent 220 may have a higher oxidation/reduction potential than the film to be polished (e.g., a metal film). As a result, the oxidizing agent 220 may oxidize the film to be polished to improve the polishing speed for the film to be polished. The oxidizing agent 220 may include a peroxide-based compound. For example, the oxidizing agent 220 may include at least one of hydrogen peroxide (H₂O₂), hydrogen peroxide-urea, or peracetic acid.

The content of the oxidizing agent 220 may according to example embodiments be about 0.1 wt % to about 10 wt % based on 100 wt % of the slurry composition 200 for chemical mechanical polishing. If the content of the oxidizing agent 220 is less than 0.1 wt %, the polishing speed for the film to be polished may be reduced. If the content of the oxidizing agent 220 exceeds about 10 wt %, excessive oxidative etching may occur, resulting in a decrease in the flatness of the film to be polished. According to further embodiments, the content of the oxidizing agent may be 0.5 wt % to 8 wt % or 1 wt % to 6 wt % based on 100 wt % of the slurry composition 200 for chemical mechanical polishing.

In some aspects, the slurry composition 200 for chemical mechanical polishing may include a plurality of polishing particles 210. The slurry composition 200 for chemical mechanical polishing may further include a solvent for dispersing the polishing particles 210. The solvent may be any liquid that can substantially uniformly disperse the polishing particles 210, and is not particularly limited. The solvent may be an aqueous solvent or an organic solvent. More specifically, the dispersion medium may be an aqueous solvent such as water, deionized water, and ultrapure water. Optionally, the solvent may be an organic solvent such as a fatty alcohol with carbon numbers of 1 to 15 or an ether with carbon numbers of 2 to 20.

In some aspects, the slurry composition 200 for chemical mechanical polishing may further include a leveling agent for reducing irregularities on the surface to be polished. The leveling agent may include or be ammonium chloride, ammonium lauryl sulfate, polyethylene glycol, polyoxyethylene alkyl ether, triethanolamine sulfate, polyvinylpyrrolidone, and/or polyacrolein, etc. The leveling agent may be mixed with the slurry composition 200 for chemical mechanical polishing at a mixing ratio of about 0.1 wt % to about 1 wt %, or 0.2 wt % to 0.9 wt %.

The piezoelectric material 212 may include a first piezoelectric material 214 (depicted as a first particle of a first piezoelectric material) and a second piezoelectric material 216 (depicted as a second particle of a second piezoelectric material) bonded to the first piezoelectric material 214. The polishing particles may include one or more first particles and one or more second particles. The first piezoelectric material 214 and the second piezoelectric material 216 may be formed of the same piezoelectric material or different piezoelectric materials. Specifically, if the first piezoelectric material 214 and the second piezoelectric material 216 are formed of different piezoelectric materials, the first piezoelectric material 214 may include or be at least one of polyvinylidene fluoride (PVDF), polyvinylidene fluoride-co-trifluoroethylene (PVDF-TrFE), or poly L-lactic acid (PLA).

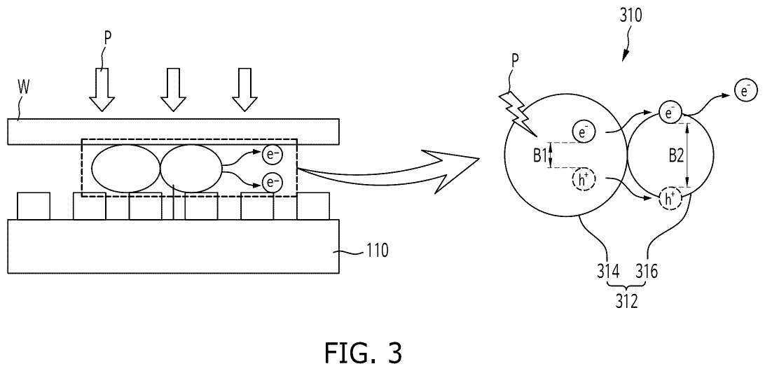

In addition, a particle size S1 of first particles of the first piezoelectric material 214 may be greater than a particle size S2 of second particles of the second piezoelectric material 216. “Particle size” as used herein refers to the diameter of the particles. As described herein, because the first piezoelectric material 214 and the second piezoelectric material 216 differ from each other in at least one of the particle size or the constituent material, bandgaps may be different from each other. Detailed examples of the first piezoelectric material 214 and the second piezoelectric material 216 will be described herein with reference to FIGS. 3 to 8B.

The slurry composition 200 for chemical mechanical polishing according to some aspects may be prepared in accordance with structures and characteristics of components of a semiconductor device with a multilayer wiring structure. For example, the slurry composition 200 for chemical mechanical polishing according to some aspects may be prepared by adding the polishing particles 210 including the piezoelectric material 212 to an aqueous medium such as distilled water at a desired concentration, and then adding the oxidizing agent 220 or oxidizing agent aqueous solution to the aqueous medium at a desired concentration. In addition, if necessary, related additives such as dispersion stabilizers, leveling agents, etc. may be added to the slurry composition 200 for chemical mechanical polishing by any method.

The slurry composition 200 for chemical mechanical polishing according to some aspects may polish one or more metal films deposited on substrates selected from the group consisting of silicon substrates, TFTLCD glass substrates, GaAs substrates and other substrates related to integrated circuits, thin films, multilayer semiconductors, and wafers. In addition, a method of manufacturing a semiconductor device using the slurry composition 200 for chemical mechanical polishing according to some aspects may be provided.

FIG. 3 is a diagram illustrating polishing particles and a polishing mechanism of a wafer using the same according to some aspects. For convenience of description, differences from the configurations described herein in FIGS. 1 and 2 will be mainly described. Corresponding elements or features to the configurations described herein in connection with FIGS. 1 and 2 may be the same as in FIGS. 1 and 2. Referring to FIG. 3, polishing particles 310 according to some aspects may include a piezoelectric material 312 including a first piezoelectric material 314 (depicted as a first particle of a first piezoelectric material) and a second piezoelectric material 316 (depicted as a second particle of a second piezoelectric material) bonded to the first piezoelectric material 314. The polishing particles 310 and the piezoelectric material 312 may replace the polishing particle 210 and the piezoelectric material 212 illustrated in FIG. 2, respectively.

The first piezoelectric material 314 and the second piezoelectric material 316 may be the same piezoelectric material as each other. A particle size of the first particles of the first piezoelectric material 314 may be greater than a particle size of the second particles of the second piezoelectric material 316. For example, the particle size of the second particles of the second piezoelectric material 316 may be 50% to 80% of the particle size of the first particles of the first piezoelectric material 314. Because the particle size of the second particles of the second piezoelectric material 316 is smaller, the magnitude of a bandgap B2 of the second piezoelectric material 316 may be greater than the magnitude of a bandgap B1 of the first piezoelectric material 314. For example, the bandgap B1 of the first piezoelectric material 314 and the bandgap B2 of the second piezoelectric material 316 may be different from each other.

The first piezoelectric material 314 and the second piezoelectric material 316 may be at least partially bonded to each other. For example, the first piezoelectric material 314 and the second piezoelectric material 316 may be bonded to each other by sintering that presses and consolidates the first piezoelectric material 314 and the second piezoelectric material 316. Alternatively, for example, the first piezoelectric material 314 and the second piezoelectric material 316 may be aggregated using any adhesive material that adheres the first piezoelectric material 314 and the second piezoelectric material 316.

A polishing mechanism of the wafer W using the polishing particles 310 according to some aspects will be described. A slurry composition for chemical mechanical polishing (e.g., the slurry composition 200 for chemical mechanical polishing of FIG. 2) including the polishing particles 310 may be applied on the polishing pad 110.

The wafer W may be disposed on the polishing pad 110 and then the pressure P may be applied, resulting in deformation of the crystal structure of the piezoelectric material 312, for example, each of the first piezoelectric material 314 and the second piezoelectric material 316, which constitutes the polishing particles 310 included in the slurry composition for chemical mechanical polishing, and as a result, the bandgap B1 of the first piezoelectric material 314 and the bandgap B2 of the second piezoelectric material 316 may be reduced. Because the bandgap B1 of the first piezoelectric material 314 has a smaller value than the bandgap B2 of the second piezoelectric material 316, an electron (e⁻) in the excited state in the first piezoelectric material 314 transitions to the conduction band, an electron (e⁻)-hole (h⁺) pair is formed, and the pair may move to the conduction band and valence band of the adjacent second piezoelectric material 316, which is bonded to the first piezoelectric material 314. Because the electron (e⁻) moves to the conduction band and the hole (h⁺) moves to the valence band, the recombination of the excited electron (e⁻) with the hole (h⁺) may be suppressed. The electrons (e⁻) and holes (h⁺) generated from the first piezoelectric material 314 and/or the second piezoelectric material 316 may react with an oxidizing agent (e.g., the oxidizing agent 220 of FIG. 2) outside the polishing particles 310 to generate OH radicals. For example, if the oxidizing agent is hydrogen peroxide (H₂O₂), OH radicals may be generated in the order of [Reaction 1] to [Reaction 4] below.

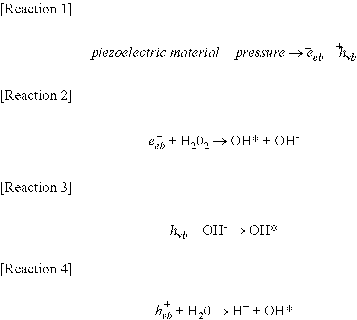

For example, if the metal film deposited on the wafer W is a tungsten film, OH radicals may oxidize the tungsten film according to [Reaction 5] as follows.

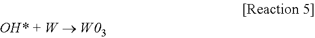

If the polishing particles 310 according to some aspects are used, the CMP process may be easily performed by oxidizing the metal film without a ferric-based additive, which may minimize damage to the CMP device and thus improve the life and stability of the CMP device. Furthermore, by bonding the piezoelectric materials with different bandgaps, the recombination of the electron (e⁻)-hole (h⁺) pair generated during the CMP process can be suppressed, thereby maximizing the piezoelectric efficiency of the polishing particles 310. Accordingly, the oxidation reaction of the metal film can be promoted, enabling an efficient CMP process.

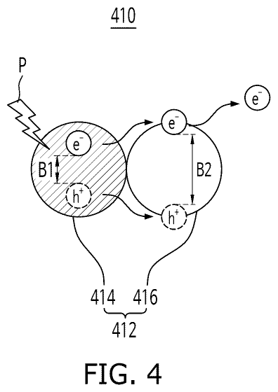

FIG. 4 is a diagram illustrating polishing particles according to some aspects. For convenience of description, differences from the configurations described in FIGS. 1 to 3 will be mainly described. Corresponding elements or features to the configurations described herein in connection with FIGS. 1 to 3 may be the same as in FIGS. 1 to 3. Referring to FIG. 4, polishing particles 410 according to some aspects may include a piezoelectric material 412 including a first piezoelectric material 414 (depicted as a first particle of a first piezoelectric material) and a second piezoelectric material 416 (depicted as a second particle of a second piezoelectric material) bonded to the first piezoelectric material 414. The polishing particles 410 and the piezoelectric material 412 may replace the polishing particle 210 and the piezoelectric material 212 illustrated in FIG. 2, respectively.

The first piezoelectric material 414 and the second piezoelectric material 416 may be different piezoelectric materials than each other. A bandgap B1 of the first piezoelectric material 414 may be less than a bandgap B2 of the second piezoelectric material 416. For example, the first piezoelectric material 414 may be barium titanate (BaTiO₃) and the second piezoelectric material 416 may be aluminum nitride (AlN). The bandgap of barium titanate may be for example, about 3.31 eV or 3.1-3.5 eV, and the bandgap of aluminum nitride may be for example, about 6 eV or 5.5 to 6.5 eV. By combining two materials with different bandgaps, the same technical effect as that of the polishing particles 310 illustrated in FIG. 3 may be achieved.

While the bandgap B1 of the first piezoelectric material 414 may be less than the bandgap B2 of the second piezoelectric material 416 as illustrated, the opposite case is also possible. For example, the bandgap B1 of the first piezoelectric material 414 may be greater than the bandgap B2 of the second piezoelectric material 416. For example, the first piezoelectric material 414 may further include at least one of polyvinylidene fluoride (PVDF), polyvinylidene fluoride-co-trifluoroethylene (PVDF-TrFE), or poly L-lactic acid (PLA), and the second piezoelectric material 416 may include or be barium titanate. For example, the first piezoelectric material 414 and the second piezoelectric material 416 may be bonded together by combining a seed of the first piezoelectric material 414 with the second piezoelectric material 416 and allowing it to grow.

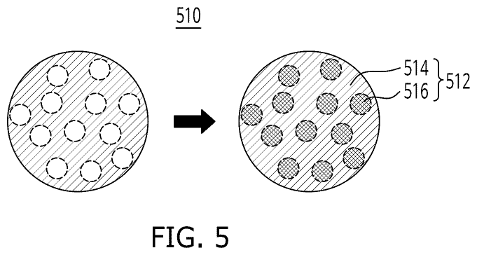

FIG. 5 is a diagram illustrating polishing particles according to some aspects. For convenience of description, differences from the configurations described in FIGS. 1 to 4 will be mainly described. Corresponding elements or features to the configurations described herein in connection with FIGS. 1 to 4 may be the same as in FIGS. 1 to 4. Referring to FIG. 5, polishing particles 510 according to some aspects may include a piezoelectric material 512 including a first piezoelectric material 514 (depicted as a first particle of a first piezoelectric material) and a second piezoelectric material 516 (depicted as a second particle of a second piezoelectric material) bonded to the first piezoelectric material 514. The polishing particles 510 and the piezoelectric material 512 may replace the polishing particle 210 and the piezoelectric material 212 illustrated in FIG. 2, respectively.

According to some aspects, a particle size of the first particle of the first piezoelectric material 514 is greater than a particle size of the second particle of the second piezoelectric material 516, and at least one second piezoelectric material 516 may be disposed within the first piezoelectric material 514. The second piezoelectric material 516 may infiltrate the first piezoelectric material 514 such that the first piezoelectric material 514 and the second piezoelectric material 516 may be bonded to each other. Alternatively, the first piezoelectric material 514 may be made of a porous material, and a plurality of second piezoelectric materials 516 may be disposed within the internal spaces of the porous material. The plurality of second piezoelectric materials 516 may be grown within the first piezoelectric material 514. The first piezoelectric material 514 and the second piezoelectric material 516 may be formed of the same material or different materials.

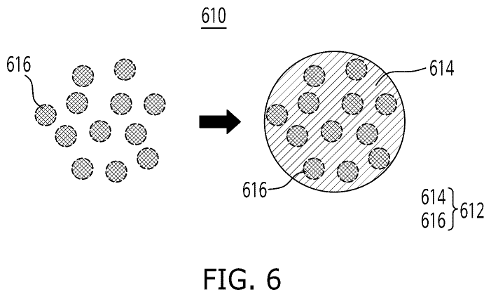

FIG. 6 is a diagram illustrating polishing particles according to some aspects. For convenience of description, differences from the configurations described in FIGS. 1 to 5 will be mainly described. Corresponding elements or features to the configurations described herein in connection with FIGS. 1 to 5 may be the same as in FIGS. 1 to 5. Referring to FIG. 6, polishing particles 610 according to some aspects may include a piezoelectric material 612 including a first piezoelectric material 614 (depicted as a first particle of a first piezoelectric material) and a second piezoelectric material 616 (depicted as a second particle of a second piezoelectric material) bonded to the first piezoelectric material 614. The polishing particles 610 and the piezoelectric material 612 may replace the polishing particle 210 and the piezoelectric material 212 illustrated in FIG. 2, respectively.

According to some aspects, a particle size of the first particles of the first piezoelectric material 614 may be greater than a particle size of the second particles of the second piezoelectric material 616, and at least one second piezoelectric material 616 may be disposed within the first piezoelectric material 614. For example, the first piezoelectric material 614 and a plurality of second particles of second piezoelectric materials 616 may be combined by allowing the first piezoelectric material 614 to grow around a plurality of second piezoelectric materials 616, which are used as seed materials. The first piezoelectric material 614 and the second piezoelectric material 616 may be formed of the same material or different materials.

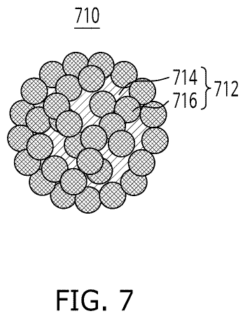

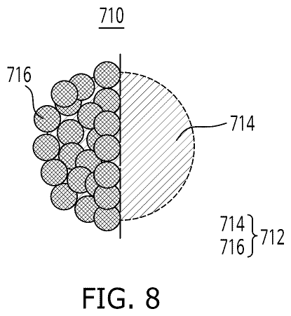

FIGS. 7 and 8 are diagrams illustrating polishing particles according to some aspects. For convenience of description, differences from the configurations described in FIGS. 1 to 6 will be mainly described. Corresponding elements or features to the configurations described herein in connection with FIGS. 1 to 6 may be the same as in FIGS. 1 to 6. Referring to FIGS. 7 and 8, polishing particles 710 according to some aspects may include a piezoelectric material 712 including a first piezoelectric material 714 (depicted as a first particle of a first piezoelectric material) and a second piezoelectric material 716 (depicted as second particles of a second piezoelectric material) bonded to the first piezoelectric material 714. The polishing particles 710 and the piezoelectric material 712 may replace the polishing particle 210 and the piezoelectric material 212 illustrated in FIG. 2, respectively.

According to some aspects, a particle size of the first particle of the first piezoelectric material 714 may be greater than a particle size of the second particle of the second piezoelectric material 716, and at least one second piezoelectric material 716 may be bonded to the surface of the first piezoelectric material 714, such as to the outer surface of the first piezoelectric material 714, to form a so-called raspberry structure or half-raspberry structure. For example, the structure of FIG. 7 may be implemented by depositing at least one second piezoelectric material 716 on the first piezoelectric material 714. For example, the structure of FIG. 8 may be implemented by partially embedding the first piezoelectric material 714 in the substrate (e.g., polymer fiber) and then depositing the second piezoelectric material 716 on the exposed surface. In other aspects, the structure of FIG. 8 may be implemented by activating only a partial surface of the first piezoelectric material 714 with ultraviolet rays and then depositing the second piezoelectric material 716 only in the corresponding region. The first piezoelectric material 714 and the second piezoelectric material 716 may be formed of the same material or different materials.

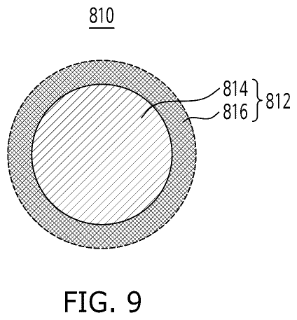

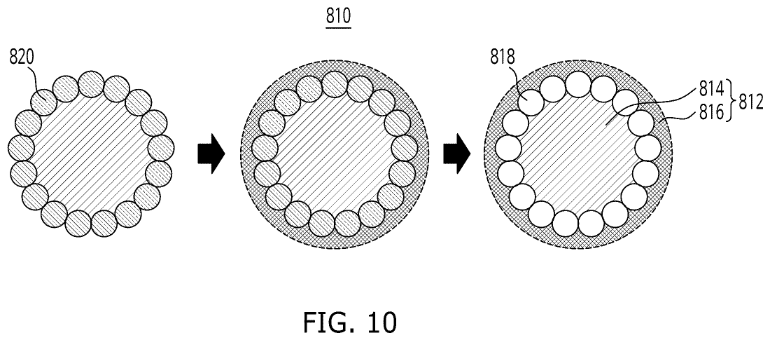

FIGS. 9 and 10 are diagrams illustrating polishing particles according to some aspects. For convenience of description, differences from the configurations described in FIGS. 1 to 8 will be mainly described. Corresponding elements or features to the configurations described herein in connection with FIGS. 1 to 8 may be the same as in FIGS. 1 to 8. Referring to FIGS. 9 and 10, polishing particles 810 according to some aspects may include a piezoelectric material 812 including a first piezoelectric material 814 (depicted as a first particle of a first piezoelectric material) and a second piezoelectric material 816 (depicted as a second particle of a second piezoelectric material) bonded to the first piezoelectric material 814. The polishing particles 810 and the piezoelectric material 812 may replace the polishing particle 210 and the piezoelectric material 212 illustrated in FIG. 2, respectively.

According to some aspects, the piezoelectric material 812 may have a core-shell structure that includes a core and a shell, in which the second piezoelectric material 816 as the shell may be disposed on the first piezoelectric material 814 as the core. For example, the second piezoelectric material 816 may be disposed to surround the first piezoelectric material 814. The polishing particles 810 may include voids 818 between the first piezoelectric material 814 and the second piezoelectric material 816. The voids 818 may be generated by depositing a sacrificial material 820 on the first piezoelectric material 814, depositing the second piezoelectric material 816 over the sacrificial material 820, and removing the sacrificial material 820. At least one void 818 may be present on the surface of the first piezoelectric material 814. The first piezoelectric material 814 having at least one void 818 may be referred to as porous raspberry or half-porous raspberry.

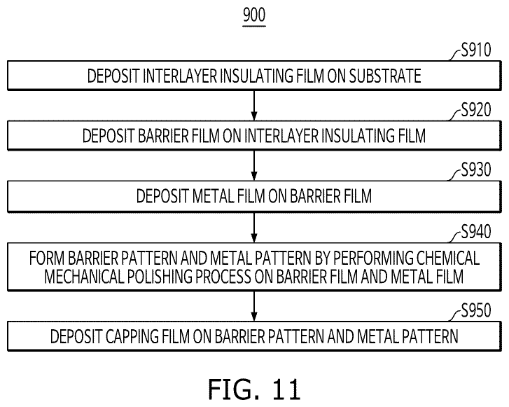

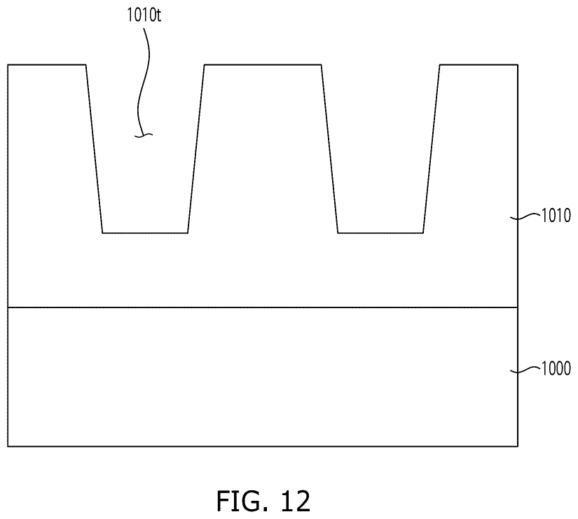

FIG. 11 is a flowchart provided to explain a method of manufacturing a semiconductor device according to some aspects. FIGS. 12 to 16 are diagrams illustrating the sequence of a method of manufacturing a semiconductor device according to some aspects. For convenience of description, differences from the configurations described in FIGS. 1 to 10 will be mainly described. Corresponding elements or features to the configurations described herein in connection with FIGS. 1 to 10 may be the same as in FIGS. 1 to 10. The method of manufacturing the semiconductor device according to FIGS. 11 to 16 is only an example, and the technical idea of the present invention is not limited to this method of manufacturing.

Referring to FIGS. 11 and 12, the method of manufacturing the semiconductor device may include an operation S910 of depositing an interlayer insulating film 1010 on a substrate 1000. The semiconductor substrate 1000 may be a configuration corresponding to the wafer W illustrated in FIG. 1. For example, the semiconductor substrate 1000 may be a bulk silicon or a silicon-on-insulator (SOI). The semiconductor substrate 1000 may be a silicon substrate or may include other materials such as silicon germanium, indium antimony, lead telluride compound, indium arsenic, indium phosphide, gallium arsenide, or gallium antimony. Alternatively, the semiconductor substrate 1000 may be a base substrate with an epitaxial layer formed thereon.

The interlayer insulating film 1010 may include a trench 1010t. For example, an etching process on the interlayer insulating film 1010 may be performed to form the trench 1010t in the interlayer insulating film 1010. For example, a width of the trench 1010t may be about 20 nm or less. For example, the width of the trench 1010t may be 1 nm to 15 nm or 3 nm to 13 nm or 5 nm to 11 nm. The interlayer insulating film 1010 may include or be an insulating material such as, for example, at least one of silicon oxide, silicon nitride, silicon oxynitride, or a combination thereof, but is not limited thereto.

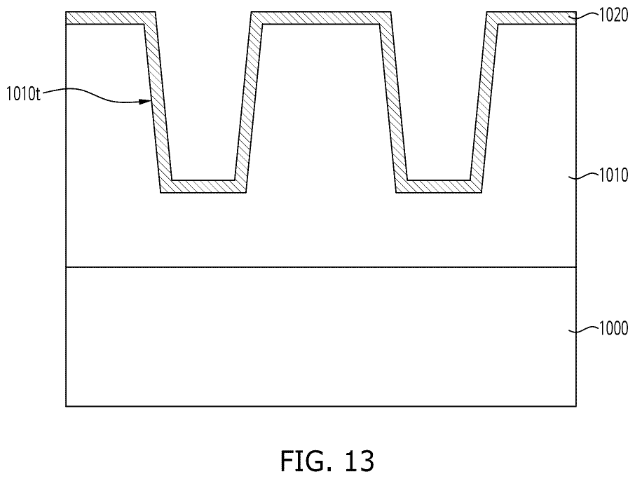

Referring to FIGS. 11 and 13, the method of manufacturing the semiconductor device may include an operation S920 of depositing a barrier film 1020 on the interlayer insulating film 1010. The barrier film 1020 may extend along a profile of the interlayer insulating film 1010 and a profile of the trench 1010t. The barrier film 1020 may include a metal or a metal nitride for preventing diffusion of a metal film 1030 of FIG. 12. For example, the barrier film 1020 may include or be at least one of titanium (Ti), tantalum (Ta), tungsten (W), nickel (Ni), cobalt (Co), platinum (Pt), an alloy thereof, nitride thereof, or a combination thereof, but is not limited thereto.

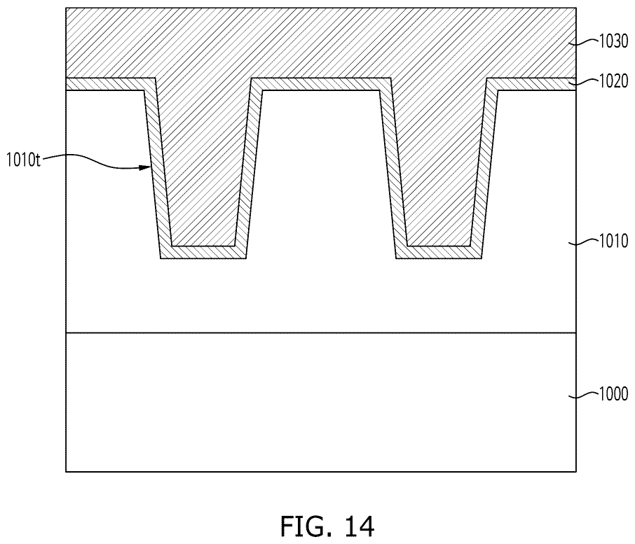

Referring to FIGS. 11 and 14, the method of manufacturing the semiconductor device may include an operation S930 of depositing the metal film 1030 on the barrier film 1020. The metal film 1030 may cover the barrier film 1020. The metal film 1030 may fill the unfilled region of the trench 1010t that remains after the barrier film 1020 has been filled. The metal film 1030 may include or be at least one of a conductive material such as, for example, tungsten (W), copper (Cu), ruthenium (Ru), molybdenum (Mo), aluminum (Al), platinum (Pt), or a combination thereof, but is not limited thereto. For example, the metal film 1030 may be tungsten (W).

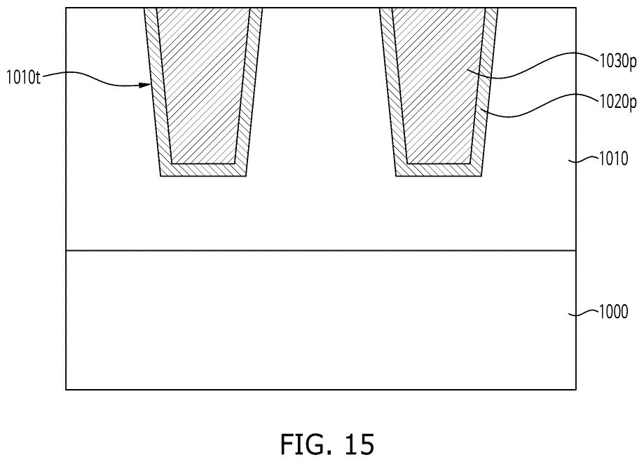

Referring to FIGS. 11 and 15, the method of manufacturing the semiconductor device may include an operation S940 of forming a barrier pattern 1020p and a metal pattern 1030p by performing a chemical mechanical polishing process on the barrier film 1020 and the metal film 1030. The slurry composition for chemical mechanical polishing described herein may be used for the chemical mechanical polishing process. For example, the chemical mechanical polishing process may be performed by the chemical mechanical polishing apparatus 100 of FIG. 1 described herein, using the slurry composition 200 for chemical mechanical polishing including the polishing particles 310 of FIG. 3. As the chemical mechanical polishing process is performed, the barrier pattern 1020p and the metal pattern 1030p may be formed in the interlayer insulating film 1010. For example, the chemical mechanical polishing process may be performed until the uppermost surface of the interlayer insulating film 1010 is exposed. The metal pattern 1030p may form a metal wiring of the semiconductor device, but is not limited thereto.

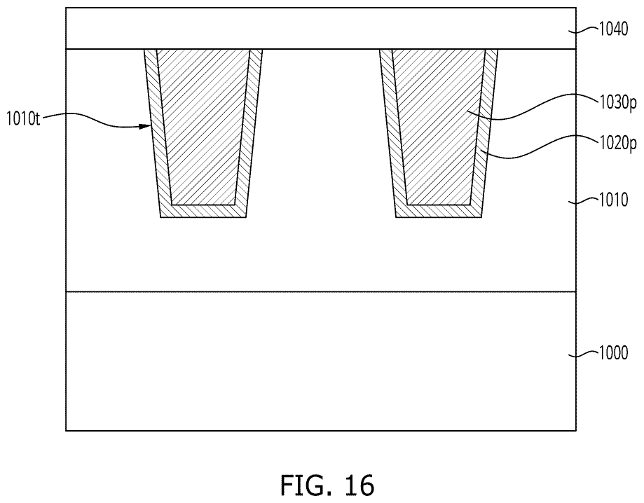

Referring to FIGS. 11 and 16, the method of manufacturing the semiconductor device may include an operation S950 of depositing a capping film 1040 on the barrier pattern 1020p and the metal pattern 1030p. The capping film 1040 may cover the interlayer insulating film 1010, the barrier pattern 1020p, and the metal pattern 1030p. The capping film 1040 may include or be an insulating material, such as at least one of silicon nitride, silicon carbide, or a combination thereof, but is not limited thereto. In other aspects, the capping film 1040 may be omitted.

The method of manufacturing the semiconductor device according to some aspects may minimize damage to the chemical mechanical polishing apparatus by using the slurry composition for chemical mechanical polishing described herein, thereby improving the life and stability of the chemical mechanical polishing apparatus. As a result, the method of manufacturing the semiconductor device according to some aspects may provide a semiconductor device with improved productivity and stability.

1. A slurry composition for chemical mechanical polishing, comprising:
polishing particles comprising a piezoelectric material; and
an oxidizing agent, wherein
the polishing particles comprise a first particle comprising a first piezoelectric material and a second particle comprising a second piezoelectric material,
the second piezoelectric material is bonded to the first piezoelectric material, and
the first piezoelectric material and the second piezoelectric material have different respective bandgaps from each other.

2. The slurry composition for chemical mechanical polishing according to claim 1, wherein a first particle size of the first particle comprising the first piezoelectric material is greater than a second particle size of the second particle comprising the second piezoelectric material.

3. The slurry composition for chemical mechanical polishing according to claim 2, wherein the second particle comprising the second piezoelectric material is disposed within the first particle comprising the first piezoelectric material.

4. The slurry composition for chemical mechanical polishing according to claim 2, wherein the second particle comprising the second piezoelectric material is bonded to a surface of the first particle comprising the first piezoelectric material.

5. The slurry composition for chemical mechanical polishing according to claim 1, wherein
the second particle comprising the second piezoelectric material is a shell disposed on the first particle comprising the first piezoelectric material, and
the first particle is a core.

6. The slurry composition for chemical mechanical polishing according to claim 5, wherein the first particle comprising the first piezoelectric material and the second particle comprising the second piezoelectric material are configured with a void between the first particle and the second particle.

7. The slurry composition for chemical mechanical polishing according to claim 1, wherein the piezoelectric material comprises at least one piezoelectric material selected from the group consisting of barium titanate (BaTiO₃), aluminum nitride (AlN), lithium titanate (LiTiO₃), lead zirconate titanate Pb(ZrTi)O₃), piezoelectric ceramic, zinc oxide (ZnO), quartz (SiO₂), and titanium dioxide (TiO₂).

8. The slurry composition for chemical mechanical polishing according to claim 1, wherein the oxidizing agent comprises at least one oxidizing agent selected from the group consisting of hydrogen peroxide (H₂O₂), urea peroxide-urea, and peracetic acid.

9. The slurry composition for chemical mechanical polishing according to claim 1, wherein the polishing particles are 0.1 wt % to 20 wt % based on 100 wt % of the slurry composition for chemical mechanical polishing.

10. The slurry composition for chemical mechanical polishing according to claim 1, wherein the first piezoelectric material and the second piezoelectric material are different materials.

11. The slurry composition for chemical mechanical polishing according to claim 10, wherein the first piezoelectric material comprises at least one piezoelectric material selected from the group consisting of polyvinylidene fluoride (PVDF), polyvinylidene fluoride-co-trfluoroethylene (PVDF-TrFE), and poly L-lactic acid (PLa).

12. A slurry composition for chemical mechanical polishing, comprising:
polishing particles comprising a piezoelectric material; and
an oxidizing agent, wherein
the polishing particles comprise a first particle comprising a first piezoelectric material and a second particle comprising a second piezoelectric material,
the second piezoelectric material is bonded to the first piezoelectric material, and
the first piezoelectric material and the second piezoelectric material differ from each other in at least one property selected from the group consisting of respective particle size and respective material.

13. The slurry composition for chemical mechanical polishing according to claim 12, wherein a first particle size of the first particle comprising the first piezoelectric material is greater than a second particle size of the second particle comprising the second piezoelectric material, and the second particle is disposed within the first particle.

14. The slurry composition for chemical mechanical polishing according to claim 12, wherein a first particle size of the first particle comprising the first piezoelectric material is greater than a second particle size of the second particle comprising the second piezoelectric material, and the second particle is bonded to a surface of the first particle.

15. The slurry composition for chemical mechanical polishing according to claim 12, wherein
the second particle comprising the second piezoelectric material is a shell disposed on the first particle comprising the first piezoelectric material, and
the first particle is a core.

16. The slurry composition for chemical mechanical polishing according to claim 12, wherein the piezoelectric material comprises at least one piezoelectric material selected from the group consisting of barium titanate (BaTiO₃), aluminum nitride (AlN), lithium titanate (LiTiO₃), lead zirconate titanate, Pb(ZrTi)O₃, piezoelectric ceramic, zinc oxide (ZnO), quartz (SiO₂), titanium dioxide (TiO₂), polyvinylidene fluoride (PVDF), polyvinylidene fluoride-co-trifluoroethylene (PVDF-TrFE), and poly L-lactic acid (PLLA).

17. A method of manufacturing a semiconductor device, comprising:
forming a metal film on a substrate; and
performing a chemical mechanical polishing process on the metal film using a slurry composition for chemical mechanical polishing, wherein
the slurry composition for chemical mechanical polishing comprises:
polishing particles comprising a piezoelectric material; and
an oxidizing agent, and
the polishing particles comprise a first particle comprising a first piezoelectric material and a second particle comprising a second piezoelectric material,
the second piezoelectric material is bonded to the first piezoelectric material, and
a first bandgap of the first piezoelectric material and a second bandgap of the second piezoelectric material are different from each other.

18. The method according to claim 17, wherein the bonding of the first piezoelectric material and the second piezoelectric material is performed by:
a sintering method that presses the first particle and the second particle and consolidates the first piezoelectric material and the second piezoelectric material; or
an aggregation method that adheres the first piezoelectric material and the second piezoelectric material together with an adhesive material.

19. The method according to claim 17, wherein
a first particle size of the first particle comprising the first piezoelectric material is greater than a second particle size of the second particle comprising the second piezoelectric material, and
the second particle is formed by growing the second piezoelectric material within the first piezoelectric material formed of a porous material.

20. The method according to claim 17, wherein a first particle size of the first particle is greater than a second particle size of the second particle, and a second particle is formed by being deposited on a surface of the first particle.
